(19) United States
(12) Patent Application Publication
(10) Pub. No.: US 2007/0082454 A1
(43) Pub. Date: Apr. 12, 2007

(54) Microelectronic device and method of manufacturing a microelectronic device

(75) Inventors: Ralph Stommer, Neubiberg (DE); Marc Strasser, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/247,982

(22) Filed: Oct. 12, 2005

(51) Int. Cl. H01L 21/76; H01L 23/62; H01L 23/58

(52) U.S. Cl. 438/424; 257/665

(57) ABSTRACT

A microelectronic device comprises a substrate and a transistor. The transistor comprises a channel region in the substrate, a recess in the channel region, a first dielectric layer and a second dielectric layer. The first dielectric layer comprises a first dielectric material and is deposited at the bottom of the recess. The second dielectric layer comprises a second dielectric material and is deposited at a sidewall of the recess. The dielectric constant of the first dielectric material is higher than the dielectric constant of the second dielectric material. A gate electrode is positioned in the recess and is electrically insulated from the channel region by the first and second dielectric layers.

### TECHNICAL FIELD OF THE INVENTION

The present invention refers to a microelectronic device and a method of manufacturing a microelectronic device, and in particular, a microelectronic device having a recessed channel array transistor (RCAT) and/or a trench capacitor.

### BACKGROUND OF THE INVENTION

The manufacturing costs of microelectronic devices are essentially proportional to the chip area. And there is a continuous tendency to increase the number of transistors, capacitors and other elements in microelectronic devices. For both reasons, microelectronic devices and their single electronic elements are continuously miniaturized. For this purpose, the linear dimensions of each electronic element are reduced and new designs for transistors, capacitors and other elements are developed.

For example, the gate electrode, the gate oxide and the channel region of a field effect transistor (FET) have been flat and essentially parallel to the surface of a substrate for a long period of time. The FIGS. 6 to 8 display a more recent design of a transistor. In a substrate 10 with a surface 12, a high aspect ratio recess, or trench 14 is formed essentially vertical to the surface 12 of the substrate 10. A thin dielectric layer 16 made of silicon oxide or any other electrically insulating material is deposited in the recess 14. The recess is filled with doped polysilicon or any other electrically conductive material forming a gate electrode 18. Highly doped source and drain electrode regions 20, 22 are formed at the surface 12 of the substrate 10 at opposite sides of the trench 14. A thin U-shaped channel region 24 is formed in the substrate 10 directly adjacent to the dielectric layer 16.

The electrical conductivity of the channel region 24 can be controlled by the electrical potential of the gate electrode 18 thereby electrically conductively connecting the source and drain electrode regions 20, 22 or insulating the same from each other. The local conductivity of the channel region 24 at any location depends on the local electrical field and the resulting local electrical potential at that location. However, the electrical field is strongly inhomogeneous at the lower end or bottom of the trench 14.

FIGS. 6 to 8 display three different examples of the shape of the trench 14. The circles 30 indicate regions with reduced electrical field. These regions of reduced electrical field exist at all edges or corners of the trench 14. The value of the gate electrode 18 potential necessary for switching on the channel region 24 in these low electrical field regions 30 is considerably higher than for other parts of the channel regions 24, and the electrical potential of the gate electrode 18 necessary to switch on the entire channel region 24 strongly depends on the particular geometry of the lower end of the trench 14. Further, local variations of the dopant concentration strongly influence these electrical properties.

However, it is very difficult to control the particular shape of the trench 14. While the geometry displayed in FIG. 7 is slightly better than the geometries displayed in FIGS. 6 and 8, it can hardly be reproduced reliable. The actual geometry of the trench 14 most probably deviates from the geometry of FIG. 7 with a more or less pronounced tendency towards the geometries of FIGS. 6 and 8. This results in strong variations of the electrical properties from transistor to transistor.

While FIGS. 6 to 8 display vertical gate FETs, or RCATs, similar problems of a hardly reproducible trench geometry strongly influencing electric and electronic properties exist for trench capacitors and other trench electronic elements of microelectronic devices as well. It is a further problem that not only the geometry of the trench 14 but also the thickness and the homogeneity of the thickness of the dielectric layer 16 are difficult to control.

### SUMMARY OF THE INVENTION

The present invention provides an improved microelectronic device and an improved method of manufacturing a microelectronic device, the microelectronic device having an electronic element formed in a recess. The present invention also provides a microelectronic device and a method of manufacturing a microelectronic device, the microelectronic device having a transistor or capacitor formed in a recess. The present invention also provides a microelectronic device and a method of manufacturing a microelectronic device wherein the influence of the specific geometry of a recess on the electrical and electronic properties of an electronic element of the microelectronic device is eliminated or reduced. The present invention also provides a microelectronic device and a method of manufacturing a microelectronic device wherein the microelectronic device is a memory device.

In one embodiment of the present invention there is a microelectronic device comprising a substrate and a transistor, the transistor comprising: a channel region in the substrate; a recess in the channel region; a first dielectric layer being deposited at the bottom of the recess, the first dielectric layer comprising a first dielectric material; a second dielectric layer being deposited at a sidewall of the recess, the second dielectric layer comprising a second dielectric material; and a gate electrode positioned in the recess and being electrically insulated from the channel region by the first and second dielectric layers, wherein the dielectric constant of the first dielectric material is higher than the dielectric constant of the second dielectric material.

In another embodiment of the present invention there is a microelectronic device with: a substrate comprising an electrically conductive material in an electrically conductive region; a recess formed in the electrically conductive region; a first dielectric layer being deposited at the bottom of the recess, the first dielectric layer comprising a first dielectric material; a second dielectric layer being deposited at a sidewall of the recess, the second dielectric layer comprising a second dielectric material; and a filling member positioned in the recess and being electrically insulated from the electrically conductive material of the electrically conductive region by the first and second dielectric layers.

In still another embodiment of the present invention there is a method of manufacturing a microelectronic device, the method comprising: providing a substrate with a surface; producing an electrically conductive region under the surface of the substrate; producing a recess in the electrically conductive region; generating a first dielectric layer at the bottom of the recess; generating a second dielectric layer at a sidewall of the recess; and filling the recess with a filling material, thereby forming a filling member, wherein the filling member is electrically insulated from the electrically conductive region by the first and second dielectric layers.

In yet another embodiment of the invention, there is a microelectronic device and a method of manufacturing a microelectronic device wherein a first dielectric layer comprising a first dielectric material is deposited at the bottom of a recess and a second dielectric layer comprising a second dielectric material is deposited at a sidewall of the recess. The first and second dielectric materials are different from each other and preferably provide different dielectric constants. The first dielectric material of the first dielectric layer is selected such that the influence of the particular geometry of the bottom of the recess on the electrical or electronic properties of the element is reduced or eliminated. Thus the present invention provides the advantage that there is no need to control the geometry of the bottom of the recess. Thereby the manufacturing costs are reduced.

In another embodiment of the invention, the microelectronic device with a transistor formed in the recess wherein the dielectric constant of the first dielectric material is higher than the dielectric constant of the second dielectric material. Adjacent to the first dielectric layer the electrical conductivity of the channel region is increased at an electrode voltage the absolute value of which is lower than the absolute value of the electrode voltage necessary to increase the electrical conductivity of the channel region adjacent to the second dielectric layer. Thereby, the conductivity of the entire channel and the switching behaviour and the threshold voltage of the transistor are merely influenced by the essentially vertical sidewalls of the recess but not by the geometry of the bottom of the recess.

In one aspect of the invention, the high dielectric constant of the first dielectric material of the first dielectric layer at the bottom of the recess causes a kind of short circuit of the channel at the bottom of the recess. At a gate electrode potential at the transition between the off state and the on state of the transistor (threshold voltage) that part of the channel adjacent to the first dielectric layer is already locally in the on state. The transition between the off state and the on state of the transistor is a transition of merely the sidewall parts of the channel. This is particularly advantageous since the geometry of the essentially vertical sidewalls of the recess and thereby the switching behaviour of the sidewall parts of the channel are easily controlled with a high reproducibility. In particular, the influence of local variations of the dopant concentration is reduced.

The present invention, in another embodiment, forms a dielectric layer comprising the second dielectric material at the sidewalls and at the bottom of the recess and to implant nitrogen or other ions into the dielectric layer at the bottom of the recess thereby locally transforming the second dielectric material to the first dielectric material. This method provides the advantage that the nitrogen or other ions are easily implanted selectively at the bottom of the recess by means of a vertical stream of energized ions. The stream vertical to the surface of the substrate and parallel to the sidewalls of the recess causes a concentration of implanted ions which is much higher at the bottom of the recess than in its sidewalls.

The implantation of ions is a standard technology. The concentration and the depth of implantation can be easily controlled. However, it is not necessary to control the concentration of nitrogen or other ions in the bottom part of the dielectric layer with high accuracy. It is a further advantage of the present invention that due to the small depth of implantation it is not necessary to protect the surface of the substrate outside the recess against the ions. For example, the electrical properties of source and drain regions under the surface of the substrate are scarcely modified by the implantation of nitrogen in a shallow surface layer.

The present invention also provides the microelectronic device with a capacitor formed in the recess. The first dielectric material of the first dielectric layer at the bottom of the recess preferably provides a dielectric constant which is lower than the dielectric constant of the second dielectric material of the second dielectric layer at the sidewalls of the recess. Thereby, the contribution of the bottom region to the capacitance of the capacitor and the influence of the geometry of the bottom of the recess on the capacity of the capacitor are reduced. In this way the present invention provides the advantage that the capacitance can be set precisely more easily.

The present invention is particularly advantageous for highly miniaturized elements like cell transistors or storage capacitors of storage cells of memory devices or other microelectronic devices.

### BRIEF DESCRIPTION OF THE DRAWINGS

The invention is described in more detail with reference to the exemplary embodiments and figures, in which:

FIG. 1 shows a sectional view of a microelectronic device according to an embodiment of the present invention.

FIG. 2 shows a sectional view of a microelectronic device according to an embodiment of the present invention.

FIG. 3 shows a sectional view of a microelectronic device according to an embodiment of the present invention.

FIG. 4 shows a sectional view of a microelectronic device according to an embodiment of the present invention.

FIG. 5 shows a flow chart of a method according to an embodiment of the present invention.

FIGS. 6 to 8 show sectional views of conventional microelectronic devices.

### DETAILED DESCRIPTION OF THE INVENTION

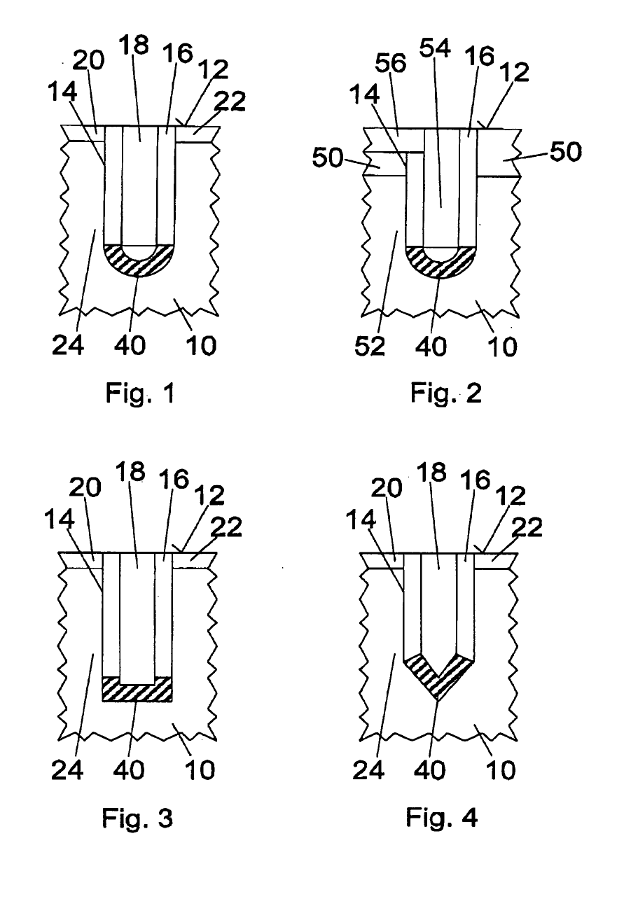

FIGS. 1 to 4 display schematic sectional views of parts of microelectronic devices wherein the sectional area is perpendicular to the surface 12 of a substrate 10. Each of the microelectronic devices displayed in FIGS. 1 to 4 are transistor devices or capacitor devices or any other devices comprising memory cells. However, the present invention is advantageous for all highly miniaturized microelectronic devices with electronic elements formed in or at a recess.

FIG. 1 is a schematic view of a microelectronic device according to an embodiment of the present invention. The microelectronic device comprises a substrate 10 with a surface 12. A recess or trench 14 is formed vertical to the surface 12 of the substrate 10. Preferably the trench 14 provides a high aspect ratio and essentially vertical sidewalls. The bottom of the recess 14 is covered with a first dielectric layer 40, and the sidewalls of the recess 14 are covered with a second dielectric layer 16. A gate electrode 18 is arranged in the recess 14 and is electrically insulated from the substrate 10 by the first and second dielectric layers 40, 16. A source electrode or source electrode region 20 and a drain electrode or drain electrode region 22 are formed at the surface 12 of the substrate 10 on opposite sides of and adjacent to the trench 14. A channel region 24 in the substrate is adjacent to the trench 14.

Preferably, the substrate comprises Si or Ge or GaAs or any other crystalline or polycrystalline or amorphous semiconductor material. The source and drain electrode regions 20, 22 are highly doped with a dopant concentration of 10¹⁹ cm⁻³ . . . 10²¹ cm⁻³. The substrate 10 or at least the channel region 24 in the substrate 10 is preferably lightly doped with a dopant concentration of 10¹⁶ cm⁻³ . . . 10¹⁸ cm⁻³. Preferably, the first dielectric material of the first dielectric layer 40 comprises silicon oxynitride or silicon nitride or hafnium oxide or hafnium oxynitride or hafnium nitride wherein the stoichiometry of silicon or hafnium oxide can be variable. Preferably, the second dielectric material of the second dielectric layer 16 is silicon oxide. Preferably, the width of the trench 14 is between 50 nm and 100 nm or even smaller and the depth of the trench 14 is between 100 nm and 200 nm or even larger. Preferably, the thickness of the first and second dielectric layers 40, 16 is between 1.5 nm and 10 nm. Preferably the gate electrode 18 comprises highly doped polysilicon or tungsten or any other metal or any other electrically conductive material.

For an NFET, the source and drain electrode regions 20, 22 are n-doped, the substrate 10 or at least the channel region 24 is p-doped and the gate electrode 18 is n-doped if it comprises a semiconductor. For a PFET, the source and drain electrode regions 20, 22 are p-doped, the substrate 10 or at least the channel region 24 is n-doped and the gate electrode 18 is p-doped if it comprises a semiconductor.

The dielectric constant of the first dielectric material of the first dielectric layer 40 is higher than the dielectric constant of the second dielectric material of the second dielectric layer 16. For example, the relative dielectric constant εᵣ of silicon oxide SiO₂ is εᵣ=3.9, and the relative dielectric constant of pure silicon nitride Si₃N₄ is εᵣ=7.5. For the first dielectric material comprising silicon, oxygen and nitrogen, the relative dielectric constant of the first dielectric layer is 3.9<εᵣ<7.5 depending on the nitrogen content.

Along the interface between the substrate 10 and the first and second dielectric layers 40, 16, an electrically conductive inversion layer, or channel, electrically conductively connecting the source and drain electrodes 20, 22 can be formed in the channel region 24. The formation of the conductive channel depends on the electrostatic potential of the gate electrode 18 and on the voltages between the gate electrode 18 and the source and drain electrodes 20, 22 and the substrate 10. Due to the dielectric constant of the first dielectric layer 40 being higher than the dielectric constant of the second dielectric layer 16, adjacent to the first dielectric layer 40 the channel is formed earlier than adjacent to the second dielectric layer 16.

In other words, at a potential of the gate electrode 18 at which no channel is formed adjacent to the second dielectric layer 16 but close to the threshold at which a channel is formed adjacent to the second dielectric layer 16, a channel is formed adjacent to the first dielectric layer 40. Thereby, the switching behaviour of the transistor formed by the source and drain electrodes 20, 22, the gate electrode 18 and the channel region 24 is largely independent of the geometry of the bottom of the trench 14.

The threshold voltage, or threshold potential of the transistor is the threshold voltage, or threshold potential, respectively, at which the source and drain electrodes 20, 22 are electrically conductively connected via a channel in the channel region 24. Due to the dielectric constant of the first dielectric material being higher than the dielectric constant of the second dielectric material, the threshold voltage of the transistor is largely independent of the particular geometry of the bottom of the recess 14. In other words, due to the dielectric constant of the first dielectric material being higher than the dielectric constant of the second dielectric material, at the threshold voltage of the transistor the channel region adjacent to the first dielectric layer 40 is short circuited.

It has been found that with usual nitrogen implantation parameters the influence of edges or other structures at the bottom of the trench 14 on the threshold voltage of the transistor can be compensated as long as the radius of curvature is not less than twice the thickness of the dielectric layers 40, 16.

FIG. 2 is a schematic view of a part of a microelectronic device according to another embodiment of the present invention. The second embodiment differs from the first embodiment in that a capacitor instead of a transistor is formed in a trench 14. The microelectronic device comprises a substrate 10 with a surface 12 and an electrically insulating layer 50 at the surface 12. A recess or trench 14 is formed in the electrically insulating layer 50 and in the substrate 10 and is vertical to the surface 12. Preferably, the trench 14 provides a high aspect ratio and essentially vertical sidewalls.

A first dielectric layer 40 is deposited at the bottom of the trench 14, and a second dielectric layer 16 is deposited at the sidewalls of the trench 14. At least in a region adjacent to the trench 14, the substrate 10 is electrically conductive and forms a first capacitor electrode 52. The trench 14 is filled with doped polysilicon, tungsten or any other metal or electrically conductive material forming a second capacitor electrode 54. The second capacitor electrode 54 is connected to a conductor 56. In this example, the conductor 56 is oriented parallel to the surface 12 and arranged in the electrically insulating layer 50.

The first and second dielectric layers 40, 16 provide different dielectric materials. Preferably, the dielectric constant of the first dielectric material of the first dielectric layer 40 is lower than the dielectric constant of the second dielectric material of the second dielectric layer 16. In this way the influence of the geometry of the bottom of the trench 14 on the capacitance of the capacitor is reduced. The value of the capacitance of the capacitor is better defined and more reliable and the fluctuations of the capacitance from capacitor to capacitor is reduced.

Whereas the geometry of the bottom of the trench 14 displayed in FIGS. 1 and 2 is somewhat idealized, the actual geometry in a real device will always deviate from the optimum geometry with a semicircular cross section to some extent. The actual geometry depends on the crystalline structure of the substrate 10, the etching process and its parameters and can be subject to strong random influences.

Two extreme geometries are displayed in FIGS. 3 and 4. While the cross sectional shape of trench 14 in the embodiment displayed in FIG. 3 is essentially rectangular, the cross section of the bottom of the trench 14 of the embodiment displayed in FIG. 4 has a V-shape. Although the FIGS. 3 and 4 display transistors similar to the transistor displayed in FIG. 1, the same trench geometries may occur at the capacitor displayed in FIG. 2.

It is advantageous to provide a microelectronic device with both a transistor as described above with reference to FIG. 1 and a capacitor as described above with reference to FIG. 2. Preferably, the transistor is a cell transistor and the capacitor is a storage capacitor of a memory cell, the trenches and the dielectric layers of which being produced simultaneously.

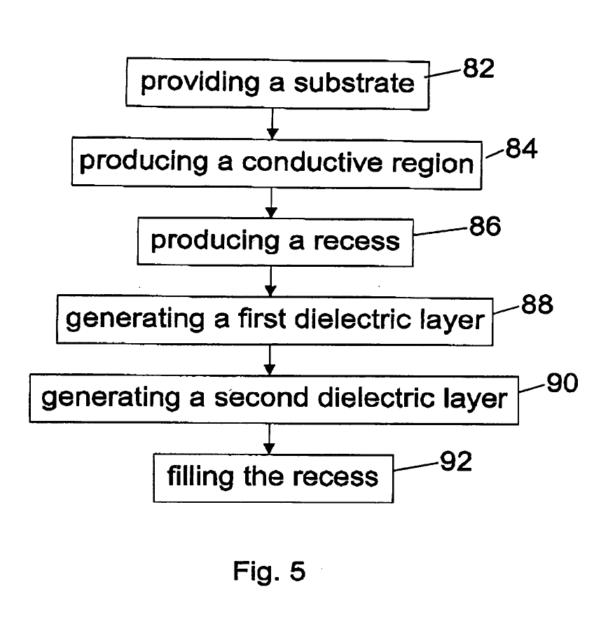

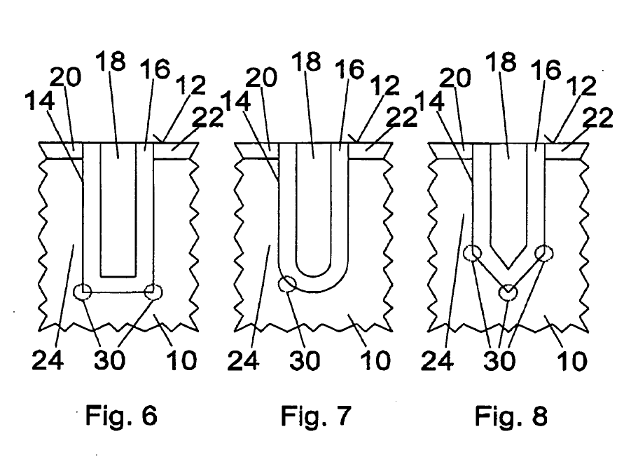

FIG. 5 is a schematic flow chart of a method according to an embodiment of the present invention. The method is a method of manufacturing a microelectronic device, wherein the microelectronic device is preferably a memory device or any other device comprising memory cells, and wherein the below described steps are performed for forming a cell transistor and/or a storage capacitor.

In a first step 82, a substrate 10 with a surface 12 is provided. In a second step 84, a conductive region 24, 52 is produced in the substrate 10. This is preferably done by doping the substrate material. In a third step 86, a recess 14 is produced in the conductive region 24, 52. Preferably, this recess is a trench with a high aspect ratio and is produced by an anisotropic etching process. The recess 14 provides sidewalls which are essentially vertical to the surface 12 of the substrate 10.

In a fourth step 88, a first dielectric layer 40 comprising a first dielectric material is generated at the bottom of the recess 14. In a fifth step 90, a second dielectric layer 16 comprising a second dielectric material is generated. The fourth and fifth steps 88, 90 can be performed in this sequence or in the reverse sequence or even simultaneously. According to a preferred embodiment, a dielectric layer is generated in the recess 14 comprising for example silicon oxide. Subsequently ions, for example nitrogen ions, are implanted in the dielectric layer at the bottom of the recess 14. The dielectric material of the dielectric layer portion 16 at the sidewalls of the recess 14 without implanted atoms is the second dielectric material of the second dielectric layer. By the implantation of the atoms, the original dielectric material is transformed to the first dielectric material of the first dielectric layer 40.

Alternatively, the first and second dielectric layers 40, 16 are generated separately. According to this alternative, low-k dielectrics like stoichiometric or non-stoichiometric silicon oxynitride, pure silicon nitride, hafnium oxide, hafnium oxynitride or pure hafnium nitride can be used as first dielectric material with a high dielectric constant.

When the electronic element formed with this method is a capacitor, the dielectric constant of the second dielectric layer 16 is preferably higher than the dielectric constant of the first dielectric layer 40, the first dielectric material is preferably silicon oxide and the second dielectric material is preferably selected from the group comprising silicon oxynitride, silicon nitride, hafnium oxide, hafnium oxynitride and hafnium nitride.

In a sixth step 92, the recess is filled with an electrically conductive material like doped polysilicon, tungsten, any other metal or any other electrically conductive material.

What is claimed is:

1. A microelectronic device having a substrate and a transistor, the transistor comprising:
a channel region in the substrate;
a recess in the channel region;
a first dielectric layer being deposited at a bottom of the recess, the first dielectric layer comprising a first dielectric material;
a second dielectric layer being deposited at a sidewall of the recess, the second dielectric layer comprising a second dielectric material; and
a gate electrode positioned in the recess and being electrically insulated from the channel region by the first and second dielectric layers,
wherein the dielectric constant of the first dielectric material is higher than the dielectric constant of the second dielectric material.

2. The microelectronic device according to claim 1, wherein the first dielectric material is selected from the group comprising silicon oxynitride, silicon nitride, hafnium oxide, hafnium oxynitride and hafnium nitride and wherein the second dielectric material is silicon oxide.

3. The microelectronic device according to claim 1, wherein the recess provides a shape of a trench with essentially vertical sidewalls.

4. The microelectronic device according to claim 2, wherein the recess provides a shape of a trench with essentially vertical sidewalls.

5. The microelectronic device according to claim 1, wherein the microelectronic device is a memory device.

6. The microelectronic device according to claim 2, wherein the microelectronic device is a memory device.

7. The microelectronic device according to claim 3, wherein the microelectronic device is a memory device.

8. A microelectronic device, comprising:
a substrate comprising an electrically conductive material in an electrically conductive region;
a recess formed in the electrically conductive region;
a first dielectric layer being deposited at a bottom of the recess, the first dielectric layer comprising a first dielectric material;
a second dielectric layer being deposited at a sidewall of the recess, the second dielectric layer comprising a second dielectric material; and
a filling member positioned in the recess and being electrically insulated from the electrically conductive material of the electrically conductive region by the first and second dielectric layers.

9. The microelectronic device according to claim 8, wherein
the electrically conductive region forms a first capacitor electrode of a capacitor,
the filling member forms a second capacitor electrode of the capacitor, and
the first and second dielectric layer form a dielectric of the capacitor.

10. The microelectronic device according to claim 8, wherein the dielectric constant of the first dielectric material is higher than the dielectric constant of the second dielectric material.

11. The microelectronic device according to claim 10, wherein the first dielectric material is selected from the group comprising silicon oxynitride, silicon nitride, hafnium oxide, hafnium oxynitride and hafnium nitride and wherein the second dielectric material is silicon oxide.

12. The microelectronic device according to claim 8, wherein the recess provides the shape of a trench with essentially vertical sidewalls.

13. The microelectronic device according to claim 9, wherein the recess provides a shape of a trench with essentially vertical sidewalls.

14. A method of manufacturing a microelectronic device, comprising:
providing a substrate with a surface;
producing an electrically conductive region under the surface of the substrate;
producing a recess in the electrically conductive region;
generating a first dielectric layer at a bottom of the recess;
generating a second dielectric layer at a sidewall of the recess; and
filling the recess with a filling material, thereby forming a filling member, wherein the filling member is electrically insulated from the electrically conductive region by the first and second dielectric layers.

15. The method according to claim 14, wherein
the electrically conductive region comprises a channel region, and
the filling member is a gate electrode.

16. The method according to claim 14, wherein
the first dielectric layer is generated with a first dielectric constant,
the second dielectric layer is generated with a second dielectric constant, and
the first dielectric constant is higher than the second dielectric constant.

17. The method according to claim 15, wherein
the first dielectric layer is generated with a first dielectric constant,
the second dielectric layer is generated with a second dielectric constant, and
the first dielectric constant is higher than the second dielectric constant.

18. The method according to claim 16, wherein
the electrically conductive region comprises silicon,
generating the second dielectric layer comprises producing a silicon oxide layer in the recess, and
generating the first dielectric layer comprises implanting nitrogen, the nitrogen ions being directed essentially vertically to the surface of the substrate.

19. The method according to claim 16, wherein
the electrically conductive region comprises silicon,
generating the first dielectric layer comprises implanting nitrogen, the nitrogen ions being directed essentially vertically to the surface of the substrate, and
generating the second dielectric layer comprises oxidizing silicon at the sidewall.

20. The method according to claim 14, wherein
the electrically conductive region forms a first capacitor electrode of a capacitor,
the filling member is a second capacitor electrode of the capacitor, and
the first and second dielectric layer form a dielectric of the capacitor.
